(19) United States
(12) Patent Application Publication
(10) Pub. No.: US 2006/0221587 A1
(43) Pub. Date: Oct. 5, 2006

(54) Multi-wire board, its manufacturing method, and electronic apparatus having the multi-wire board

(75) Inventor: Yoshihiro Morita, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/442,253

(22) Filed: May 30, 2006

Related U.S. Application Data
(62) Division of application No. 11/041,869, filed on Jan. 25, 2005.
Application No. 11/041,869 is a continuation of application No. PCT/JP02/07579, filed on Jul. 25, 2002.

(51) Int. Cl. H05K 1/14; H01R 12/16

(52) U.S. Cl. 361/785; 361/803

(57) ABSTRACT

A multi-wire board includes first and second substrates, and plural wires that connect the first and second substrates to each other, and expose to the outside, wherein the wires form a predetermined pattern in the first substrate.

This application is a continuation based on PCT International Application No. PCT/JP02/07579, filed on Jul. 25, 2002, which is hereby incorporated by reference herein in its entirety as if fully set forth herein.

### BACKGROUND OF THE INVENTION

The present relates generally to a printed circuit, and more particular to a circuit board and its manufacturing method. The present invention is suitable, for example, for a wiring board that integrally forms plural printed wiring boards and is mounted in a server and a hard disc drive (“HDD”).

Along with the recent increasing demand for high-performance and high-speed electronic apparatuses, a server is required to connect many motherboards to a back panel or a backboard. On the other hand, due to the demand for smaller electronic apparatuses, it becomes difficult to connect two boards to each other on the same plane.

Referring now to FIGS. 14 and 15, a description will be given of a conventional connecting method that uses a connector. Here, FIG. 14 is a sectional view of a connector 20 that is connected via through holes 14 to a circuit board 10, such as a motherboard, having a signal pattern 12. FIG. 15 is a sectional view for explaining a connection between the circuit board 10 and another circuit board 30, such as a backboard.

As shown in FIGS. 14 and 15, the circuit board 10 is mounted with an electronic device 2, such as a chip, and forms the signal pattern 12 and the through holes 14. The connector 20, which is also referred to as a right angle type connector, is fixed onto the through holes 14 in the circuit board 10, and includes connector leads 22 and contact portions 24 both serving as a conductor. On the other hand, another connector 40 is referred to as a straight-type connector, fixed onto the circuit board 30, such as the backboard, and provided with pins 42. By inserting the connector 20 into the connector 40, each pin 42 is inserted into a corresponding contact portion 24 in the connector 20. As a result, the connectors 20 and 40 are electrically connected to each other, and the circuit boards 10 and 30 are electrically connected to each other.

However, the electric characteristics of the circuit boards 10 and 30 that are connected via the connectors 20 and 40 depend upon the characteristics of the connectors 20 and 40. In the connector 20 shown in FIG. 14, the outer and inner circumference connector leads 22 have different lengths, and therefore different electric characteristics. Therefore, an electric signal deteriorates in the connector 20 due to the non-uniform electric characteristics. In addition, the connector 20 should maintain an engagement length for each pin 42 and inevitably makes the inductance large. Moreover, since a normal circuit board uses etching to form the signal pattern 12, its surface is so rough that high-frequency signal transmissions that exceed 1 GHz in an interface viewed from the server's CPU deteriorate due to the skin effect.

A so-called rigid flexible board is known as a method for connecting two circuit boards without a connector. The “rigid flexible board”, as used herein, is a wiring board that connects plural printed circuit boards (or rigid parts) to each other via a flexible wiring board (or a flexible part), and integrates them into one board. A connection of two circuit boards through a flexible board does not require two circuit boards to be placed on the same plane, and thus the rigid flexible board leads to a smaller electronic apparatus. Such a rigid flexible board is disclosed, for example, in Japanese Patent Applications, Publication Nos. 5-243738 and 4-26185.

The rigid flexible board appears to solve the above problems by using the flexible part instead of the connectors 20 and 40. However, etching forms a signal pattern in the flexible part and makes its surface still rough, causing the significant transmission loss due to the influence of the skin effect unsuitable for fast transmissions. In addition, the wiring in the flexible part generally has a small rectangular sectional area of a width of about 70 to 100 μm and a height of about 18 to 35 μm.

### BRIEF SUMMARY OF THE INVENTION

Accordingly, it is an exemplary object of the present invention to provide a novel and useful circuit board and its manufacturing method, which solve the conventional problems, and reduce the transmission loss.

A multi-wire board according to one embodiment of the present invention includes first and second substrates, and plural wires that connect the first and second substrates to each other, and expose to the outside, wherein the wires form a predetermined pattern in the first substrate. In this multi-wire board, the first and second substrates are bendable at an arbitrary angle at the wires. The wire's surface is smoother than the flexible part's wiring in the rigid flexible board, and is not subject to the skin effect. In addition, a circle is larger in sectional area than a square when the circle's diameter is as long as the square's diagonal line. Therefore, the inventive multi-wire board can maintain high-speed transmissions. The wire is used instead of the signal pattern. The first substrate may have a signal pattern that is electrically connected to the wires. In other words, the first substrate is produced as a normal circuit board and the wires may be connected to the signal pattern inside the first substrate through the edge face of the first substrate.

The multi-wire board may include plural substrates that include one of the first and second substrates, and form a polygonal shape around the other of the first and second substrates. The polygonal shape includes a triangle, a rectangle, a pentagon, a hexagon, etc. The multi-wire board may include plural substrates that include one of the first and second substrates, and the wire projecting from at least two surfaces of the first substrate. For example, the first substrate is a rectangle and the wires project from two or more sides of the rectangle. The wire may be an optical fiber cable.

An electronic apparatus according to another aspect of the present invention includes a multi-wire board that includes first and second substrates, and plural wires that connect the first and second substrates to each other, and expose to the outside, a first connector fixed onto the second substrate, a second connector connectible to the first connector, and a third substrate, onto which the second connector is fixed. This electronic has the above multi-wire board, and exhibits similar effects. This electronic has the above multi-wire board, and exhibits similar effects. The first connector is, for example, a press-fitting connector or a soldering connector. The first connector may be a pad and the second connector may be a land grid array connector.

A method according to another aspect of the present invention for manufacturing a multi-wire board that includes first and second substrates, and plural wires that connect the first and second substrates to each other, and expose to the outside, the method includes, for each of the first and second substrates, the steps of forming a first wiring layer that includes an insulating layer, on which a power supply and ground pattern is formed, forming a second wiring layer that includes a bonding layer, on which a wire forms a predetermined pattern, and applying heat and pressure to the first and second wiring layers. This method can manufacture the above multi-wire board. The forming the second wiring layer may include the step of irradiating ultrasonic waves onto the bonding layer and welding the bonding layer so as to fix the wire onto the bonding layer.

Other objects and further features of the present invention will become readily apparent from the following description of the embodiments with reference to accompanying drawings.

### BRIEF DESCRIPTION OF THE DRAWINGS

FIGS. 1A, 1B and 1C are a schematic perspective view, a schematic lateral sectional view, and a schematic longitudinal sectional view of a multi-wire board according to a first embodiment of the present invention.

FIG. 2A is a schematic perspective view showing a bending state of the multi-wire board shown in FIG. 1A, and FIG. 2B is a schematic sectional view for explaining a connection example with an external connector.

FIGS. 3A and 3B are schematic perspective and sectional views showing a structure of an LGA connector shown in FIG. 2B.

FIG. 4 is a schematic sectional view showing a connection between the multi-wire board shown in FIG. 2 and a back panel.

FIGS. 5A and 5B are schematic perspective and sectional views showing a variation of the multi-wire board shown in FIGS. 2A and 2B.

FIGS. 6A and 6B are schematic perspective and sectional views showing another variation of the multi-wire board shown in FIGS. 2A and 2B.

FIGS. 7A and 7B are schematic perspective and sectional views showing still another variation of the multi-wire board shown in FIGS. 2A and 2B.

FIGS. 8A and 8B are schematic perspective and sectional views of a variation of the substrate in the multi-wire board shown in FIG. 1.

FIG. 9 is a graph showing a relationship between a signal frequency and a signal transmission loss for a substrate in the multi-wire board shown in FIG. 1 and a substrate shown in FIG. 8 or a conventional rigid flexible board.

FIG. 10 is a schematic sectional view showing an example of use of a press-fitting connector instead of the LGA connection shown in FIG. 4.

FIG. 11A is a schematic perspective view of an electronic apparatus, to which the multi-wire board shown in FIG. 1 is applicable, and FIG. 11B is a schematic perspective view showing a circuitry housed in the electronic apparatus.

FIGS. 12A to 12F are sectional views for explaining a manufacturing method of the multi-wire board.

FIG. 13 is a flowchart for explaining a manufacturing method of the multi-wire board.

FIG. 14 is a sectional view for explaining a conventional connection using a connector.

FIG. 15 is a sectional view for explaining a conventional connection using a connector.

### DETAILED DESCRIPTION OF PREFERRED EMBODIMENT

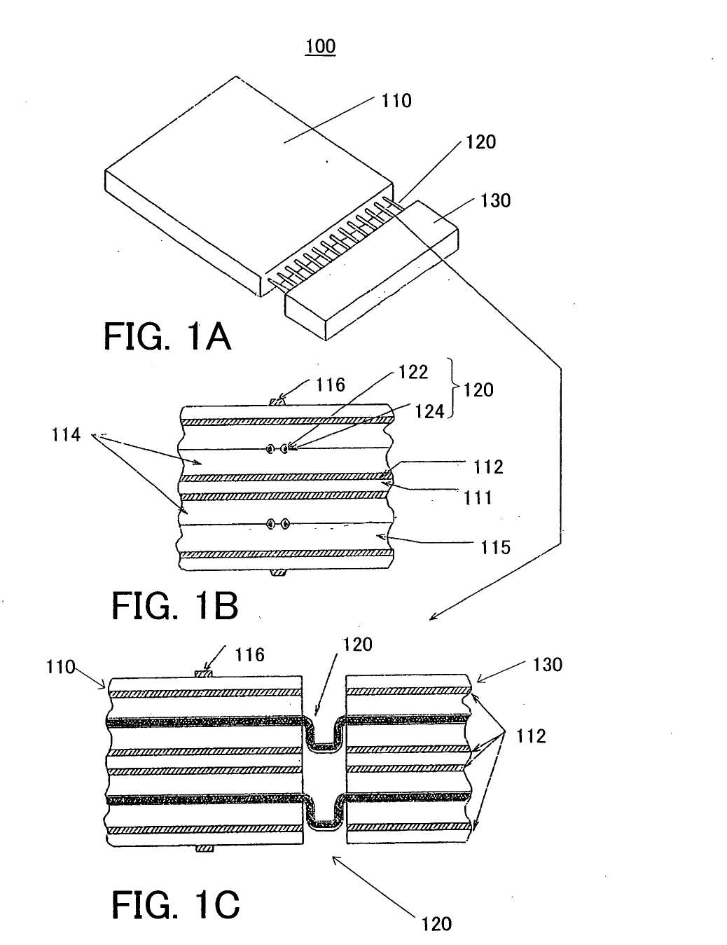

A description will be given of a multi-wire board 100 according to a first embodiment of the present invention with reference to the accompanying drawings. The multi-wire board 100 includes two substrates 110 and 130, and plural wires 120 that expose between these substrates 110 and 130 and makes these substrates 110 and 130 bendable. Here, FIG. 1A is a schematic perspective view of the multi-wire board 100. FIG. 1B is a sectional view of the substrate 110. FIG. 1C is a sectional view of the multi-wire board 100. Unless otherwise specified, the reference numeral 100 generalizes the reference numeral 100A, etc.

Since the substrates 110 and 130 have the same structure as shown in FIG. 1C in the instant embodiment, only the substrate 110 will be described. Referring to FIG. 1B, the substrate 110 includes a core 111, some inner power supply ground layers 112, some bonding layers, a pair of prepregs 115, and a pair of surface layers, and some wires 120. The core 111 is made, for example, of epoxy or polyimide added insulating resin. The power supply ground layer 112 have two functions of the power supply and the earth. The bonding layer 114 is an interlaminar bonding layer. The prepreg 115 is epoxy or polyimide added insulating resin called glass cross. The surface layer 116 is a signal pattern formed on the surface. Of course, a shape, size etc. of the substrates 110 and 130 are not limited.

The wire 120 exposes to the outside between the substrates 110 and 130, and makes the substrates 110 and 130 bendable. The wire 120 includes, for example, a conductor portion (or shaft) 122 having a diameter of 80 μm and an insulating coating portion 124 having a thickness of 20 μm. The conductor portion 122 is made, for example, copper, and the insulating coating portion 124 is made, for example, polyimide. Alternatively, the wire 120 is made of a coaxial cable where the shaft 122 is made of copper, coated with Teflon, copper mesh, and insulating coating portion 124 in this order. The wire 120 may be made of an optical fiber cable that has a core and a clad.

A sectional area of the wire 120 is larger than the conventional signal pattern that has a height of 18 to 35 μm and a width of about 70 to 100 μm, and suitable for higher-speed transmissions. The wire 120 has such a smooth surface that the skin effect does not significantly deteriorate the transmission due to the skin effect. The number of the wires 120 and an interval between the wires 120 are not limited. While FIG. 1A shows that the wires 120 are aligned in the certain direction, the direction is not limited because the substrates 110 and 130 arrange desired circuit patterns.

The power supply ground layers 112 are layered, as shown in FIG. 1B, on both sides of the core 111, and the bonding layer 114 is formed on each power supply ground layer 112. The wires 120 are arranged on each bonding layer 114, and the surface layer 116 is formed via the prepreg 115 and the power supply ground layer 112.

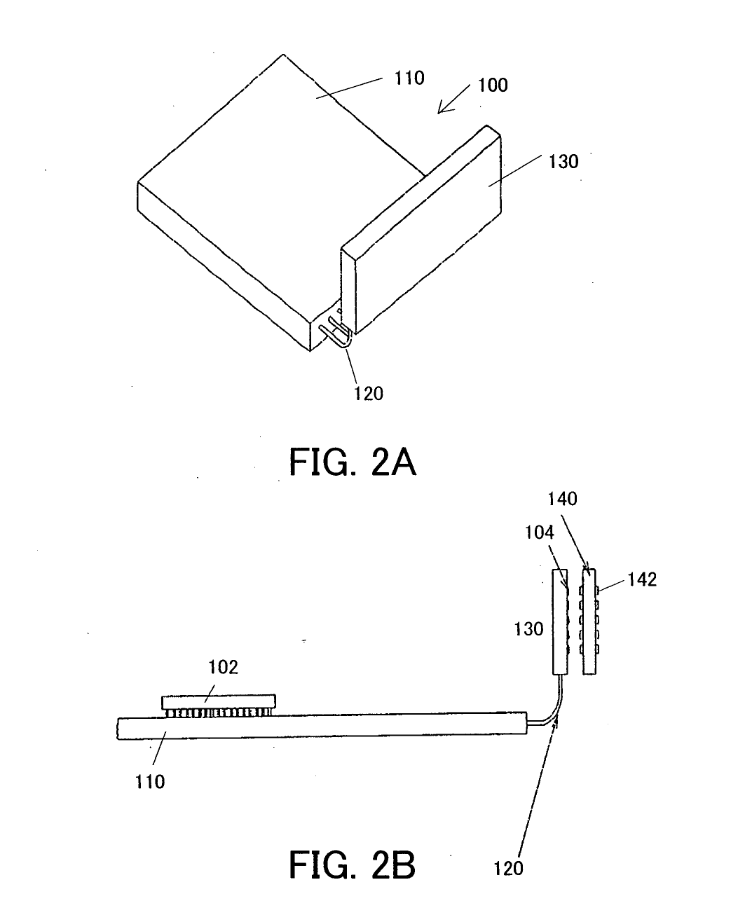

The wire 120 makes the substrates 110 and 130 bendable, for example, by 90° as shown in FIGS. 2A and 2B. Here, FIG. 2A is a schematic perspective view showing a bending state of the multi-wire board 100. FIG. 2B is a schematic perspective view for explaining means for connecting the substrate 130 to an external connector. Since the substrates 110 and 130 do not have to be placed on the same plane, the electronic apparatus that houses the electronic apparatus can be compact.

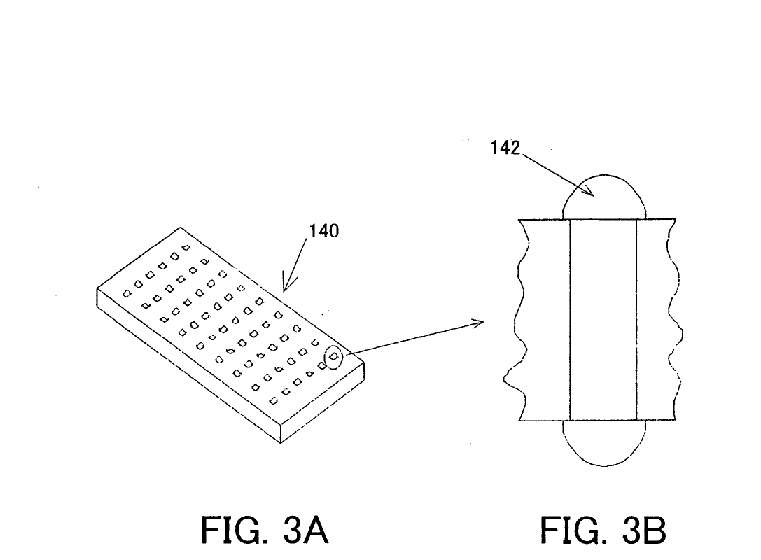

FIG. 2B is a schematic perspective view for explaining means for connecting the substrate 130 to the external connector. In FIG. 2B, the circuit device 102 is mounted on the substrate 110, and a pad 104 is attached to the back surface of the substrate 130. The pad 104 is connectible to a land grid array (“LGA”) connector or a LGA socket 140. The LGA connector 140 has conductive elastomers 142 that are elastically deformable and conductive as shown in FIG. 3, and the LGA connector 140 is connected to the pad 104 via the conductive elastomers 142. Here, FIG. 3A is a schematic perspective view of the LGA socket 140. FIG. 3B is a schematic sectional view showing a structure of the conductive elastomer 142. The conductive elastomer 142 projects from the top and back surfaces of the LGA socket 140 as shown in FIG. 3B.

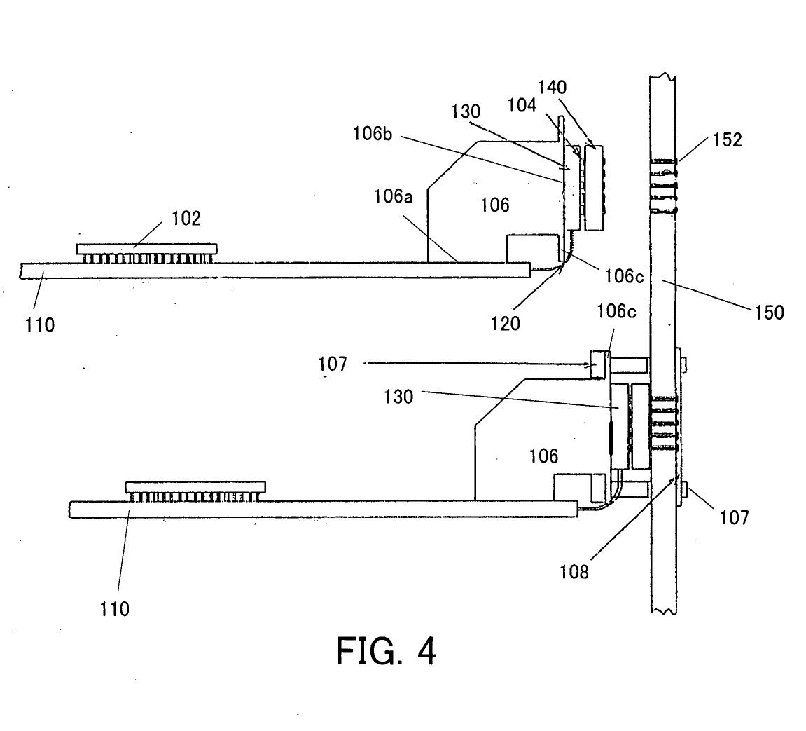

As shown in FIG. 4, the multi-wire board 100 shown in FIG. 2B is, for example, a motherboard, and the circuit device 102 is a CPU. The multi-wire board 100 is connected to a back panel or backboard 150 in a server via a fixing metal 106, some screws 107 and a bolster plate 108. Here, FIG. 4 is a schematic sectional view showing a connection between the multi-wire board 100 and the back panel 150. The conductive elastomers 142 projecting from the back surface of the LGA socket 140 are inserted into connecting holes 152 in the backboard 150.

The fixing metal 106 serves to maintain orientations of the substrates 110 and 130. The fixing metal 106 has an L shape, and is bonded to the substrate 110 at one end 106a and the substrate 130 at the other end 106b. The fixing metal 106 has one or more projections 106c having screw holes, into which the screws 170 are inserted. This screw 170 is inserted into the screw hole in the backboard 150 and fixed onto the bolster plate 108 provided on the back surface of the backboard 150.

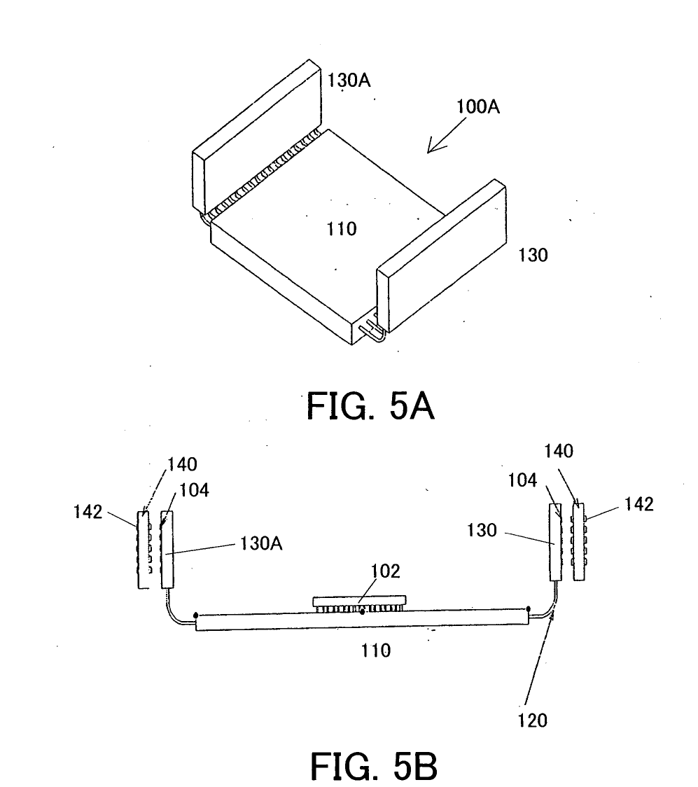

FIG. 5 shows a multi-wire board 100A as a variation of the multi-wire board 100 shown in FIG. 2. The multi-wire board 100A is different from the multi-wire board 100 in that a substrate 130A is connected to the substrate 110 at a side opposing to that for the substrate 130 via the wires 120. In this way, the wires 120 can project from plural sides of the substrate 110. Here, FIG. 5A is a schematic perspective view showing a bending state of the multi-wire board 100A. FIG. 5B is a schematic sectional view for explaining means for connecting the multi-wire board 100A to the external connector.

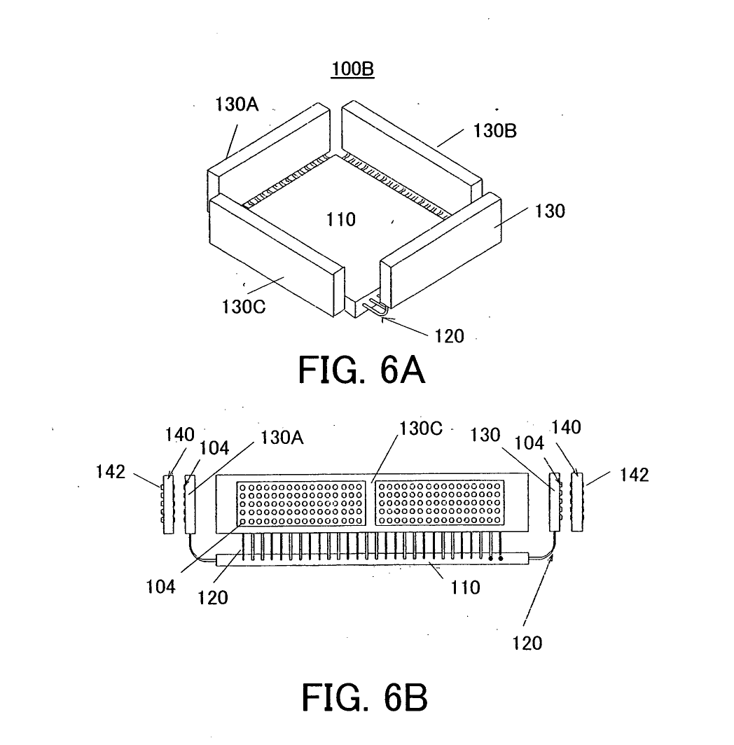

FIG. 6 is a multi-wire board 100B as another variation of the multi-wire board 100 shown in FIG. 2. The multi-wire board 100B is different from the multi-wire board 100 in that substrates 130A to 130C are connected to the substrate 110 at sides other than that for the substrate 130 via the wires 120. In this way, the wires 120 can project from all the sides of the substrate 110. Here, FIG. 6A is a schematic perspective view showing a bending state of the multi-wire board 100B. FIG. 6B is a schematic sectional view for explaining means for connecting the multi-wire board 100B to the external connector.

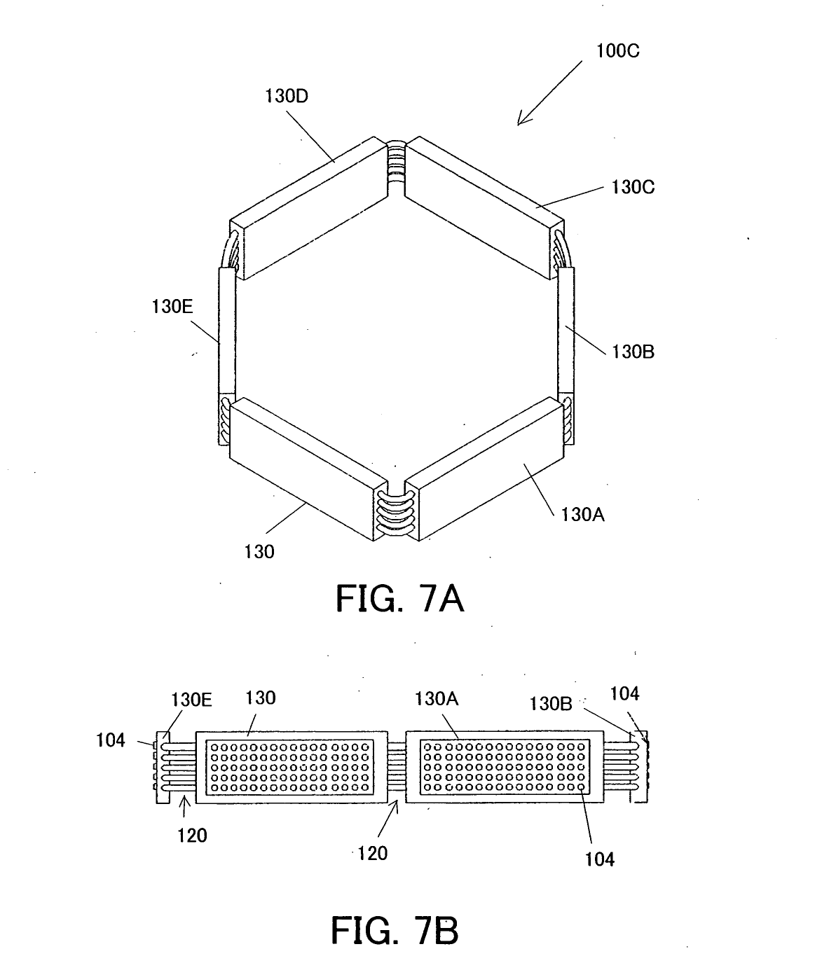

FIG. 7 is a multi-wire board 100C as still another variation of the multi-wire board 100 shown in FIG. 2. The multi-wire board 100C is different from the multi-wire board 100 in that identically sized substrates 130 to 130E form a hexagon. Each of the substrates 130 to 130E is arranged at a regular distance from a hexagonal substrate 110 located inside the hexagon and each of the substrates 130 to 130E is connected to the substrate 110 via the wires 120. The wires 120 project from all the sides of the hexagonal substrate (not shown). In this way, the substrate having the wires 120 is not limited to have a square shape and may have various polygonal shapes, such as a triangle, a rectangle, a pentagon, and a hexagon. Here, FIG. 7A is a schematic perspective view of the multi-wire board 100C. FIG. 7B is a schematic sectional view for explaining means for connecting the multi-wire board 100C to the external connector.

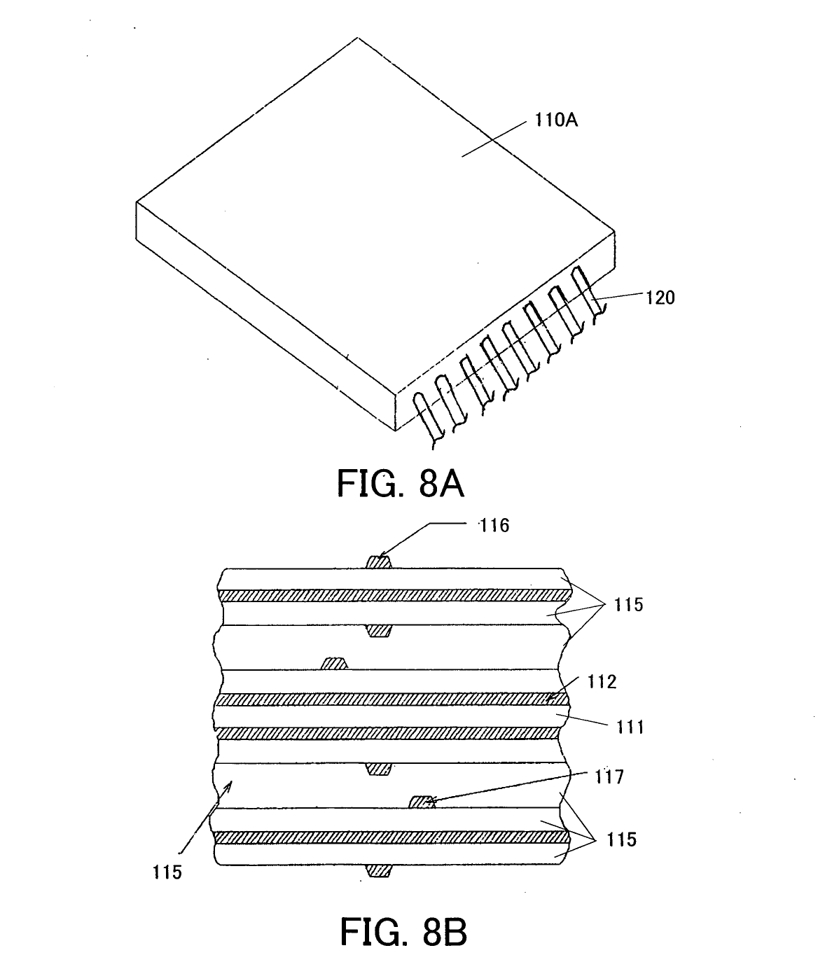

While the wires 120 form a pattern in the substrate 110 in FIG. 1B, the wires 120 may be connected to an inner signal pattern at the edge face of the substrate 110 instead of forming a circuit pattern. Referring to FIGS. 8A and 8B, a description will be given of a substrate 110A. Here, FIG. 8A is a schematic perspective view of the substrate 110A as a variation of the substrate 110. FIG. 8B is a schematic sectional view of the substrate 110A. The substrate 110A includes the core 111, the power supply ground layers 112, prepregs 115, a pair of surface layers 116, and some signal patterns 117. The signal pattern 117 is connected to the wires 120 at the end of the substrate 110A. Since the signal pattern 117 is formed by the conventional lithography that utilizes a resist application, exposure and etching, etc., its surface is rough and has a lower transmission characteristic than the wire 120.

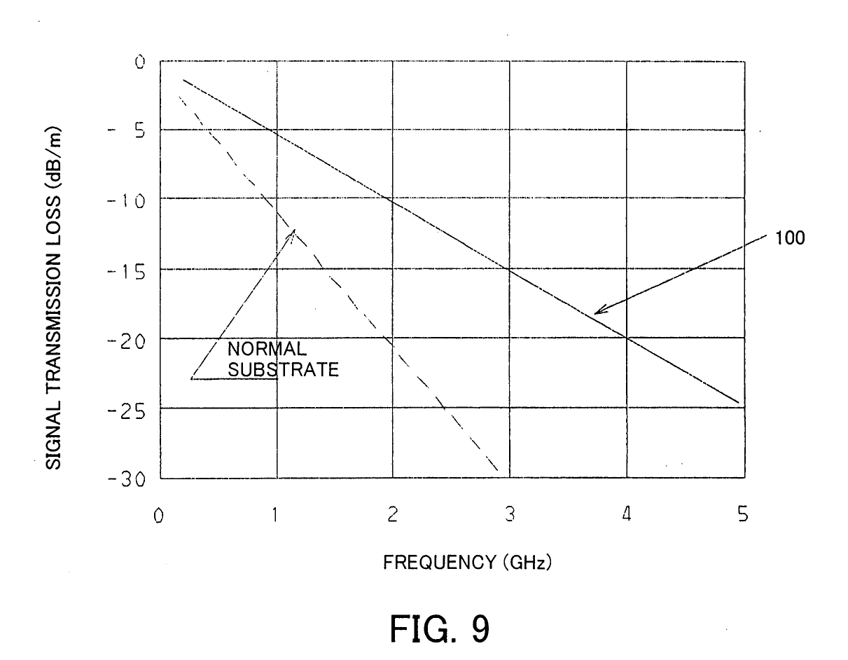

FIG. 9 is a graph of the frequency to the signal transmission loss, comparing the substrate 110 with the normal substrate or substrate 110A. A similar result is obtained even when the conventional rigid flexible substrate is used instead of the substrate 110A. It is understood from FIG. 9 that the multi-wire board 100 has less transmission loss than the substrate 110 having the signal patterns 117 or the rigid flexible board at certain frequencies.

While the following equation is met, the instant embodiment ignores the radiation loss since the radiation loss is smaller than the dissipation loss and the conductor loss:
Transmission Loss α=(Dissipation Loss αd)+(Conductor Loss αr)+(Radiation Loss)

The dissipation loss ad is expressed as follows where f is a frequency, εre is an effective dielectric constant of an insulating material and tan θ is a dielectric dissipation factor: αd=91·(εre)^{1/2}·tan θ·f

When the frequency is 1 GHz, εre, tan θ, (εre)^{1/2} and ad will be given as follows for the multi-wire board (MWB)'s substrate 110 and rigid flexible substrate (RFB) (or the substrate 110A):

| 1 GHz | εre | tanθ | (εre)^{1/2} · tanθ | αd |
|---|---|---|---|---|
| MWB | 4.7 | 0.023 | 0.049 | −4.4 |
| RFB | 3.7 | 0.019 | 0.036 | −3.3 |

The conductor loss αd is given by the following equation, where Re is resistance that is subject to the surface roughness, skin effect, and shape effect, and Z₀ is impedance: αd=−4.3·Re/Z₀

The conductor loss results from the high-frequency resistance of the insulating material, and Re is greatly varied by the surface roughness, the skin effect, the shape effect, etc. When the frequency is 1 GHz, αr will be given as follows for the multi-wire board (MWB)'s substrate 110 and the rigid flexible substrate (RFB) (or the substrate 110A):

| 1 GHz | αr |
|---|---|
| MWB | −6.9 |
| RFB | −3.4 |

As a result, the transmission loss a will be given as follows, when the frequency is 1 GHz, for the multi-wire board (MWB)'s substrate 110 and the rigid flexible substrate (RFB) (or the substrate 110A):

| 1 GHz | α |
|---|---|
| MWB | −11.3 |
| RFB | −6.7 |

It is understood from the above tables that the multi-wire board 100 has a superior transmission characteristic to that of the normal board, conventional RFB, etc.

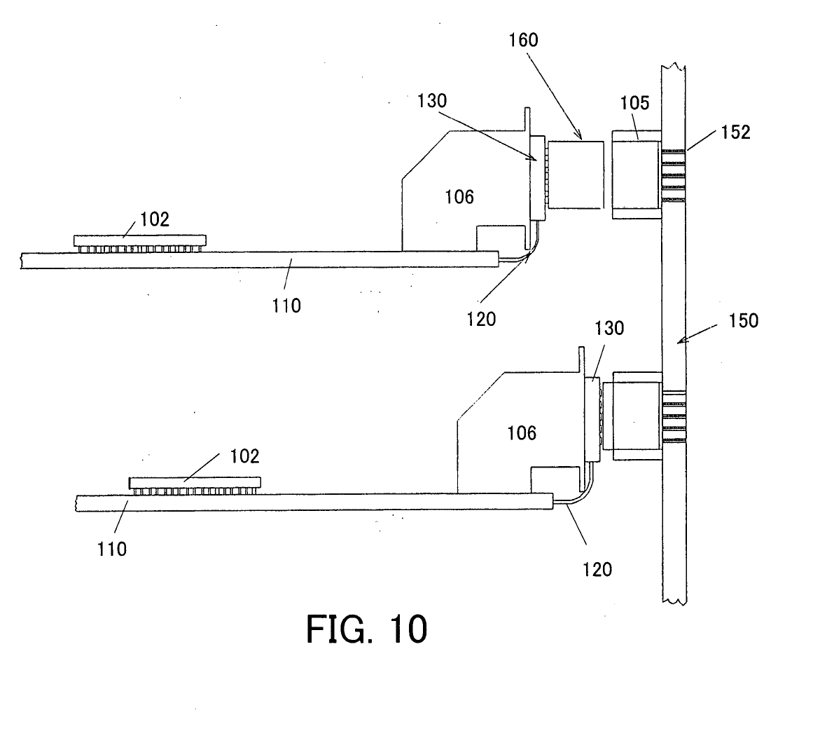

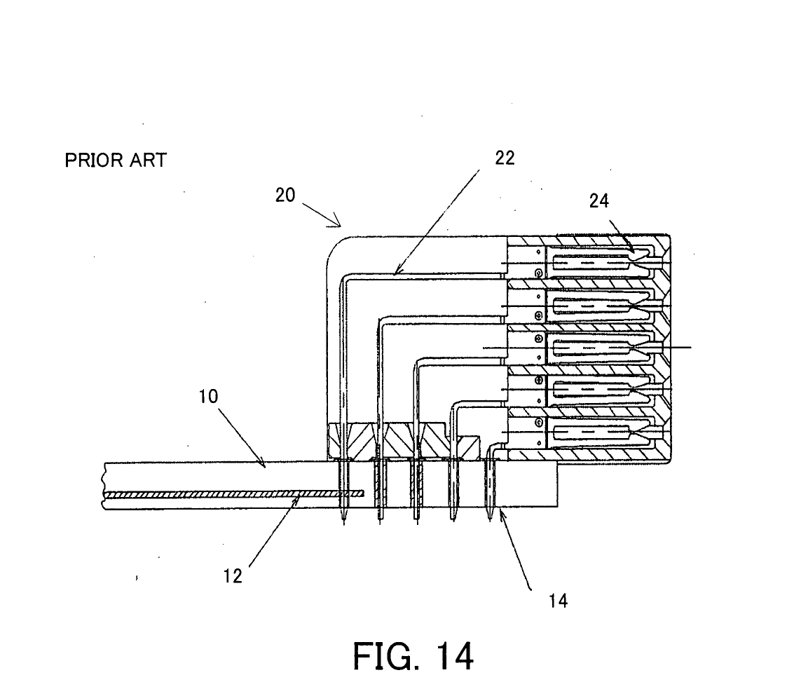

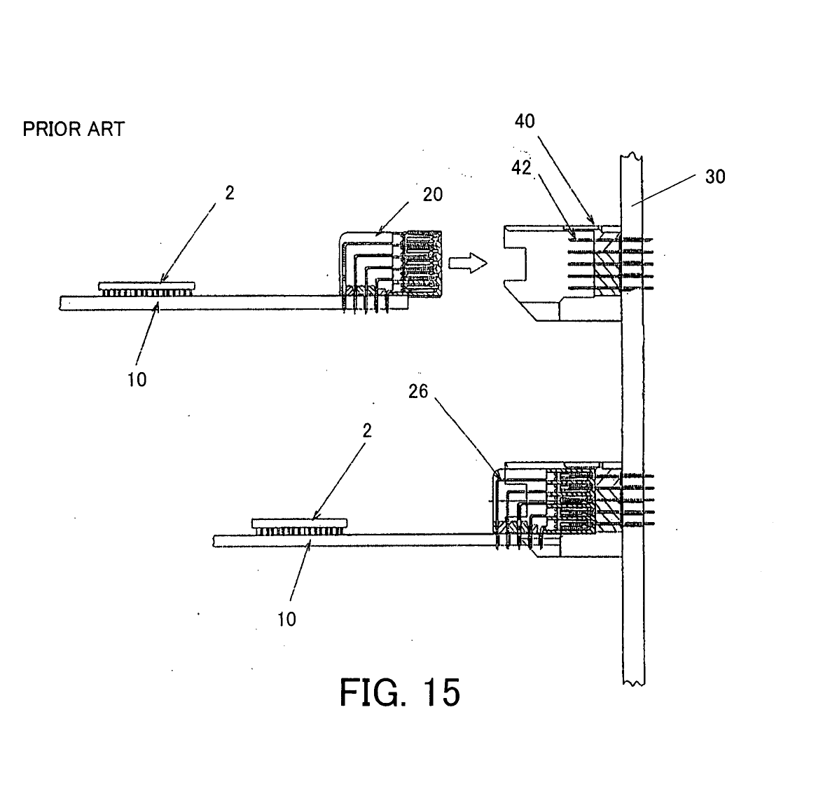

While FIG. 4 attaches the LGA connector 140 to the substrate 130 and the LGA connector 140 to the backboard 150, use of the LGA connector 140 is not vital as shown in FIG. 10. Here, FIG. 10 is a schematic sectional view showing an example of use of the press-fitting connector 160 instead of the LGA connector 140. The press-fitting connector 160 has a body and plural contact pins that project from the side or bottom of the body, and is similar to that explained with reference to FIG. 15. However, unlike FIG. 14, the instant embodiment uses the straight type instead of the right angle type. Since the instant embodiment does not use the right angle type, no problems discussed with reference to FIGS. 14 and 15 would occur. In the instant embodiment, the press-fitting connector 160 is inserted into a connector 165 provided on the backboard 150. The press-fitting connector 160 may be replaced with a soldering connector. Since the soldering connector is commercially available from FCI Inc., Lot Nos. 74983-X02ZZZ, 74981 -X02, etc. a description thereof will be omitted.

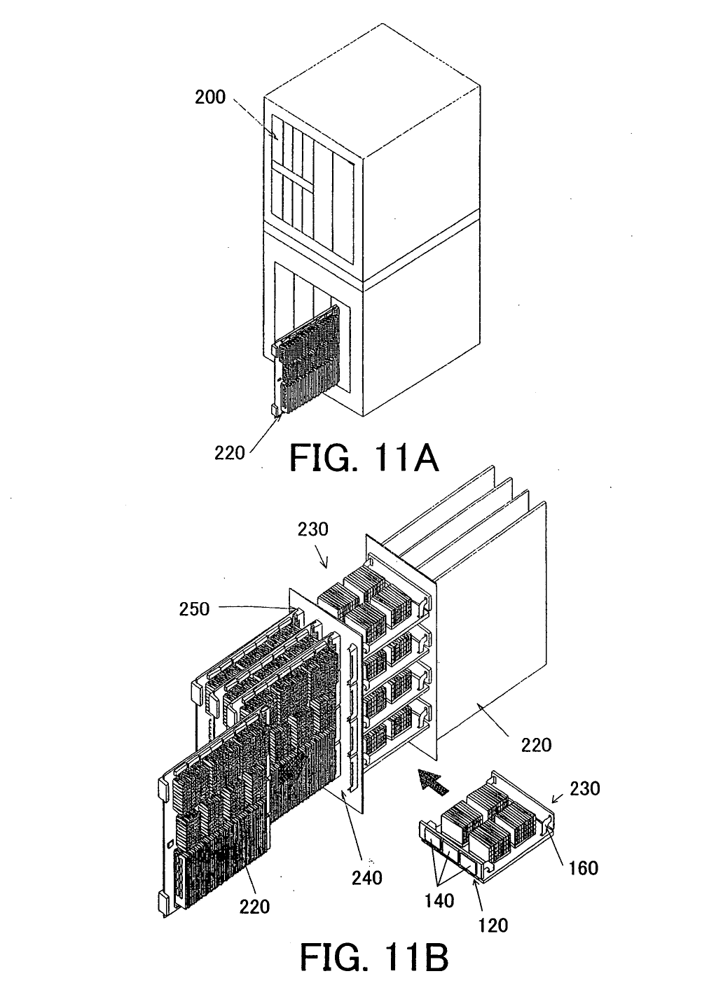

A description will now be given of the electronic apparatus 200 that applies the inventive multi-wire board 100 with reference to FIG. 11. The electronic apparatus 200 is a server and a HDD. Here, FIG. 11A is a perspective overview of the electronic apparatus 200, and FIG. 11B is a schematic perspective view showing a circuitry housed in the electronic apparatus 200.

The electronic apparatus 200 includes a power supply unit 210, motherboards 220 and 230, a back panel 240, and a connector 250, and the multi-wire board 100A shown in FIG. 5 is applied to the motherboard 230. The motherboard 230 has the LGA socket 140 and is connected to the back panel 240.

Further, the present invention is not limited to these preferred embodiments, and various variations and modifications may be made without departing from the scope of the present invention. For example, while the instant embodiment discusses the server and HDD, the multi-wire board is generally applicable to the electronic apparatus, such as network devices. In addition, while FIG. 1 shows that one stage of wires 120 expose from the multi-wire board 100, two or more stages of wires 120 may be provided.

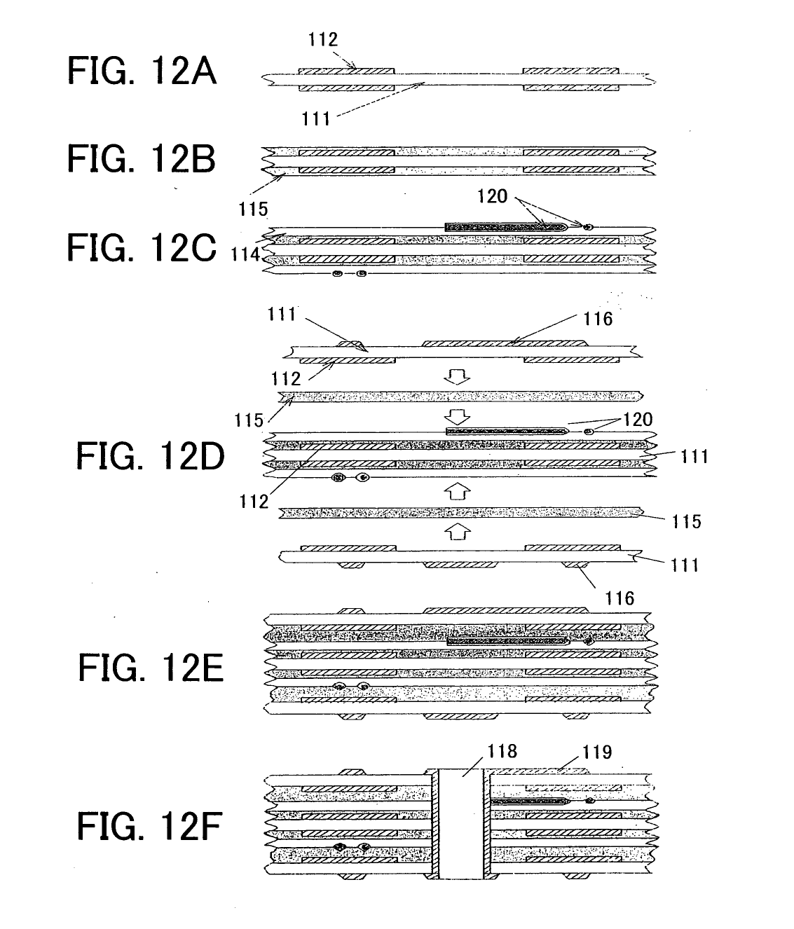

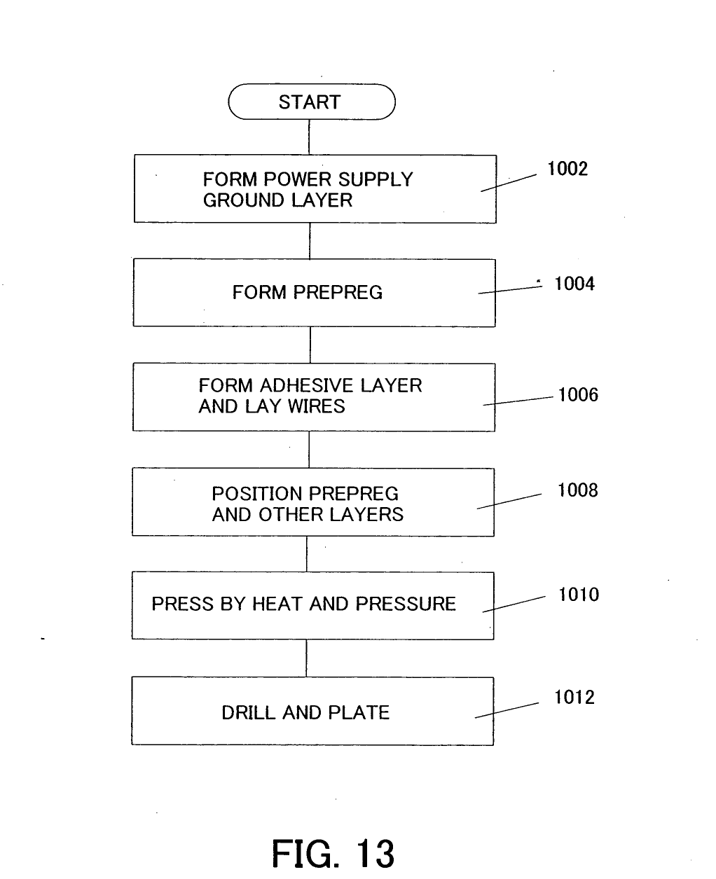

Referring now to FIGS. 12 and 13, a description will be given of a method for manufacturing the multi-wire board 100. Here, FIGS. 12A to 12F are sectional views for explaining the method for manufacturing the multi-wire board 100. FIG. 13 is a flowchart for explaining the method for manufacturing the multi-wire board 100. First, as shown in FIG. 12A, the necessary power supply ground layers 112 are formed by patterning at both sides of the core 111 (step 1002). Next, the prepregs 115 are formed at both sides (step 1004). Then, the bonding layers 114 are formed and the wires 120 are laid on the bonding layers 114 (step 1006). FIG. 12C shows the right wire 120 perpendicular to the paper surface and the left wire 120 horizontal to the paper surface. The wires 120 are arranged on the bonding layer 114 using a wiring machine, and welded and fixed onto the bonding layer 114 by irradiating the ultrasonic waves onto the bonding layer 114. Next, as shown in FIG. 12D, the surface layers 116 are positioned on the layered structure via the prepregs 115 while the power supply ground layer 112 is formed on one side of the core 111 (step 1008). Next, as shown in FIG. 12E, the layered structure is heated and compressed by a press machine (step 1010). Next, as shown in FIG. 12F, the through holes 118 are formed by forming perforation holes using a drill and plating the perforation holes (step 1012). Thereby, the surface layers 116 are connected to the wires 120. Thereafter, the chip 102 etc. are mounted on the substrate 110, and the pad 104 etc. are attached to the substrate 130. The through holes 118 can be formed, for example, around and under the chip 102 in FIG. 2D.

The multi-wire board 100 of the instant embodiment enables the two substrates 110 and 130 to be bend when they are installed in the electronic apparatus, and provides higher transmission efficiency or higher-speed and higher-quality transmission than the conventional circuit board.

The present invention can provide a novel and useful circuit board that reduces the transmission loss and its manufacturing method.

1.-5. (canceled)

6. An electronic apparatus comprising:
a multi-wire board that includes first and second substrates, and plural wires that connect said first and second substrates to each other, and expose to the outside;
a first connector fixed onto the second substrate;
a second connector connectible to said first connector; and
a third substrate, onto which said second connector is fixed.

7. An electronic apparatus according to claim 6, wherein said first connector is a press-fitting connector or a soldering connector.

8. An electronic apparatus according to claim 6, wherein said first connector is a pad and said second connector is a land grid array connector.

9.-10. (canceled)
